(19) United States
(12) Patent Application Publication
(10) Pub. No.: US 2007/0079936 A1
(43) Pub. Date: Apr. 12, 2007

(54) Bonded multi-layer RF window

(75) Inventors: Maocheng Li, Fremont, CA (US); John P. Holland, San Jose, CA (US); Patrick L. Leahey, San Jose, CA (US); Xueyu Qian, San Jose, CA (US); Michael S. Barnes, San Ramon, CA (US); Jon Clinton, Irvine, CA (US); You Wang, Cupertino, CA (US); Nianci Han, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/445,559

(22) Filed: Jun. 2, 2006

Related U.S. Application Data
(60) Provisional application No. 60/721,928, filed on Sep. 29, 2005.

(51) Int. Cl. B31B 1/60; C23F 1/00; C23C 16/00

(52) U.S. Cl. 156/345.48; 118/723 R; 156/60

(57) ABSTRACT

A bonded multi-layer RF window may include an external layer of dielectric material having desired thermal properties, an internal layer of dielectric material exposed to plasma inside a reaction chamber, and an intermediate layer of bonding material between the external layer and the internal layer. Heat produced by the chemical reaction inside the chamber and by the transmission of RF energy through the window may be conducted from the internal layer to the external layer, which may be cooled during a semiconductor wafer manufacturing process. A bonded multi-layer RF window may include cooling conduits for circulating coolant to facilitate cooling of the internal layer; additionally or alternatively, gas distribution conduits and gas injection apertures may be included for delivering one or more process gases into a reaction chamber. A system including a plasma reaction chamber may employ the inventive bonded multi-layer RF window.

### RELATED APPLICATION

This application claims priority of provisional application 60/721,928, filed Sep. 29, 2005.

### FIELD OF THE INVENTION

The present invention is related generally to plasma processing chambers, and more particularly to a bonded multi-layer dielectric window which allows coupling of RF energy into a plasma processing chamber.

### BACKGROUND OF THE INVENTION

Temperature control of the plasma within a radio frequency (RF) plasma reaction chamber has recently become an important factor in achieving and maintaining uniformity in the features produced on silicon wafers processed in such chambers. As wafer densities increase and sub-micron feature sizes continue to decrease, it is becoming more important for critical dimension control to establish predictable and stable plasma temperatures, including temperatures of walls facing and adjacent the plasma, during each process step. Unstable temperature conditions affect the ionization of the gaseous chemicals in the reaction chamber, causing plasma density and uniformity to vary. Fluctuating temperatures influence the entire reaction within the chamber, and can lead to process results which are inconsistent from one wafer to the next, or even from one die to another on a single wafer.

While precise control of the plasma temperature may be critical for many process steps, conventional RF reaction chamber systems employ a design which inherently tends to cause the plasma temperature to drift from the optimum. During fabrication, a semiconductor wafer may generally be secured on a chuck located inside the chamber. In a typical arrangement, the wafer may be secured in close proximity, for example five inches (13 mm) or closer, to the dielectric window through which RF energy is coupled into the chamber.

Conventional systems often lack effective temperature control for the dielectric RF window itself; consequently, changes in temperature of the window will influence the plasma composition and the plasma's interaction with the wafer. Further, since the wafer is typically situated close to the window, any variation in plasma composition due to the effects of window temperature influences the result of the process. Typical changes in the plasma composition are due to the effect of the temperature of the window surface on the gas particle recombination rates. Additionally, the temperature of the window may influence the deposition rates of polymers on the wind and may influence the plasma behavior through changes in the secondary electron emission coefficient of the window surface.

In addition to decreasing the reliability and efficiency of a single process, inadequate thermal control of the RF window tends to reduce the consistency of the results achieved from one process to the next. The thermal control problem may be exacerbated when the dielectric material of the RF window is repeatedly exposed to high energy RF electrical fields during successive process steps.

Wicker et al. in U.S. Pat. No. 6,033,585 disclose a multi-layer dielectric window for use in an RF plasma reaction chamber. A dielectric window couples RF energy from an external RF source into the reaction chamber. Another layer of dielectric material beneath the main window layers serves as a gas showerhead. A coolant may be circulated through the coils of an RF situated above the window for minimal temperature control. The multi-layer RF window in Wicker et al. does not however employ a bonding layer between the window and the showerhead. Instead, Wicker et al. describe either attaching the showerhead to the dielectric window or forming the showerhead channels in a green form, which is then sintered to form a unitary dielectric window and showerhead. In the former, heat transfer from the showerhead to the window is inhibited by limited surface area contact. The disclosed system suffers from the temperature control problems discussed above. Wicker et al discloses no compositional profiles for the latter.

Howald et al. in U.S. Pat. No. 6,074,516 disclose a transparent optical window of sapphire formed as a plug in a silica dielectric RF window for use in an RF plasma etch chamber requiring optical monitoring of the etch process. The sapphire improves resistance to the plasma and maintains the transparency of the optical window. The device of Howald et al does not incorporate a showerhead and provides no temperature control.

There has been a continuing and growing need for an RF window with appropriate thermal properties and heat transfer characteristics. It is desirable that temperature changes of the RF window are minimized so as not to affect the plasma in the reaction chamber. The prevention of temperature changes in the RF window requires adequate characteristics of heat transfer in order to remove excess heat produced on the inner surface of the window by the plasma process. The characteristics should also include a fast thermal response in order that the window surface temperature not exhibit temperature fluctuations as the excess heat is transferred from the inner to the outer surface of the thick dielectric window. Additionally, it is desirable that the RF window has sufficient mechanical strength to allow its use as a pressure-withstanding ceiling for the large diameter vacuum chamber required for plasma processing 300 mm wafers without requiring additional structural supports. It is also desirable that the RF window does not introduce particulate or chemical contaminants into the reaction chamber and that it be resistant to the plasma processing environment.

The most prevalent dielectric materials for plasma chamber walls and parts such as windows include quartz or silica (SiO₂) and alumina (Al₂O₃). They are strong to stand off the vacuum and are relatively inexpensive but may be readily etched in a plasma environment. Silicon nitride (Si₃N₄) is more resistant to some plasma chemistries but has a high dielectric constant and lower strength. Yttria (Y₂O₃) and to a lesser extent yttrium aluminum garnet (YAG having a composition YₓAl_{y}O_{z}) offer superior plasma etch resistance and adequate mechanical properties, but large bodies of these materials are very expensive. That is, all known dielectric materials do not provide all the desired properties for a dielectric wall of a plasma chamber.

It is well known to coating the interior of a chamber with a protective coating, for example, by plasma spraying. However, the mechanical and chemical properties of these protective coatings are typically inferior to the properties of sintered, that is, bulk ceramic materials. As a result, plasma sprayed members can generally not be used in place of bulk ceramic materials in the plasma processing chamber.

### SUMMARY OF THE INVENTION

The present invention overcomes the foregoing and other shortcomings of conventional systems by providing a bonded multi-layer dielectric wall in a plasma processing chamber. The wall may form an RF window for coupling RF energy into the chamber, for example, from an inductive coil exterior to the chamber or it may form a generally planar lid providing access to the chamber interior.

In one embodiment, inner and outer layers are bonded together as free-standing bodies with a third layer and the layers have different compositions chosen for different characteristics, such as plasma etch resistance, strength, thermal conductivity, and RF impedance.

In another embodiment, the inner and out layers are formed as green bodies of different compositions of powders loosely bonded together with a sintering agent. The bodies are co-fired to form a sintered layered structure with the powder particles partially coalescing. Preferably, an intermediate green body is sandwiched between those of the inner and outer layers and co-fired with them to serve as a transitional bonding layer.

In a further embodiment, the free-standing inner and outer layers are assembled with a glass forming powder between them. The assembly is then fired at a temperature sufficient to form a glass layer bonding the inner and outer layers but at a firing temperature below the melting points of the inner and outer layers.

Another aspect of the invention limits temperature variations in the plasma due to temperature changes in the RF window by ensuring adequate cooling of the internal surface of the RF window at all times during the reaction process. That is, the surface exposed to the interior volume of the chamber and the plasma may be actively cooled.

According to one aspect of the present invention, a bonded multi-layer RF window may generally comprise an external layer of dielectric material having desired mechanical or thermal properties and exposed to a source of RF energy, an internal layer of dielectric material exposed to plasma inside a plasma reaction chamber and having adequate plasma-resistant properties, and an intermediate layer of bonding material between the external layer and the internal layer. The bonding material may contact substantially the entire facing surface areas of both the external layer and the internal layer, to facilitate thermal conductivity from the internal layer to the external layer by broad surface area contact. Heat produced by the chemical reaction inside the chamber and by the transmission and partial absorption of RF energy through the window may be transferred away from the internal layer to the external layer, which may be cooled during a wafer fabrication process.

According to another aspect of the present invention, a bonded multi-layer RF window substantially as described above may include cooling conduits in the intermediate layer or at the interface between layers. A coolant may be circulated through the cooling conduits during operation, increasing the heat transfer from the internal layer to the external layer.

According to still another aspect of the present invention, a bonded multi-layer RF window may include gas distribution conduits in the intermediate layer or at the interface with the other two layers. Gas injection apertures may be provided in the internal layer to distribute process gases from the gas conduits into the plasma reaction chamber.

According to yet another aspect of the present invention, a system including a plasma reaction chamber may employ the inventive bonded multi-layer RF window.

The above-mentioned and other attendant advantages of the present invention will become more apparent upon examination of the following detailed description of the embodiments thereof with reference to the attached drawings.

### BRIEF DESCRIPTION OF THE DRAWINGS

FIG. 1 is a simplified cross-sectional side view of a conventional RF plasma reaction chamber.

FIG. 2 is a simplified cross-sectional side view of one embodiment of a bonded multi-layer RF window.

FIG. 3 is a simplified cross-sectional side view of another embodiment of a bonded multi-layer RF window.

FIG. 4 is a simplified cross-sectional side view of one embodiment of a bonded multi-layer RF window employing cooling conduits.

FIG. 5 is a simplified cross-sectional side view of one embodiment of a bonded multi-layer RF window employing gas distribution conduits and gas injection apertures.

FIG. 6 is a simplified cross-sectional side view of a system employing a bonded multi-layer RF window in a plasma reaction chamber.

FIG. 7 is a cross-sectional side view of a showerhead according to another embodiment of the invention.

### DETAILED DESCRIPTION OF THE PREFERRED EMBODIMENTS

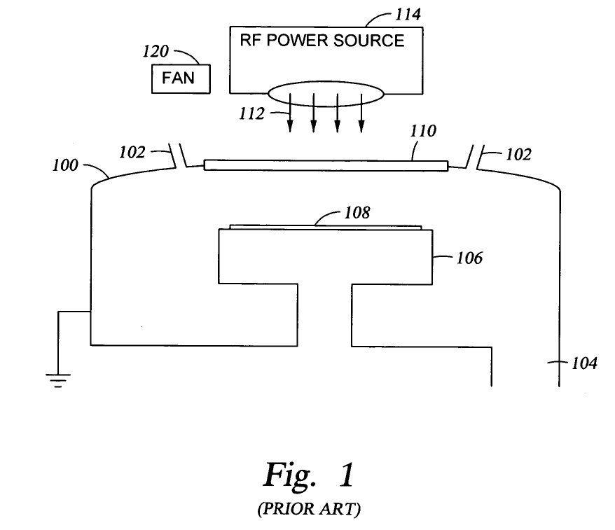

With reference now to the drawings, FIG. 1 is a simplified cross-sectional side view of a conventional RF plasma reaction chamber presently used for typical processes in the fabrication of integrated circuits in a silicon wafer. The reaction chamber 100 typically includes one or more process gas inlets 102, an exhaust port 104 connected to a vacuum pumping system, and a chuck 106 for supporting a wafer 108 to be processed. The gas inlets 102 may be in the form of a showerhead distributing the process gas over a wide area in opposition to the chuck 106. In one type of an RF plasma reaction chamber, an RF window 110 is disposed in opposition to the chuck 108 to transmit RF energy 112 generated by an RF power source 114, typically operating in the low megahertz range, to the process gases inside the reaction chamber 100. In a typical arrangement, the RF window 110 may be cooled from the outside of the reaction chamber 100. For example, a fan 120 circulates air across the back of the RF window 110. The RF source 114 may be an inductive coil antenna which is driven by an RF power supply and is placed adjacent the RF window 110. The coil antenna may be one or more solenoid coils helically wrapped around the central axis in back of the RF window 110, as is known in the IPS etch chamber of Applied Materials, as a pancake coil arranged in a planar spiral on the back of the RF window 110, as is known in the TCP etch chamber of Lam Research, or as a two-dimensional coil spirally wrapped around a dome-shaped window, as is known in the DPS etch reactor of Applied Materials of Santa Clara, Calif., or as a more complex generally planar spiral shape, as is known in the DPS II etch reactor of Applied Materials. Other coil configurations are possible. For example, an inductive coil may be wrapped around the sidewalls. Other RF sources are possible and may include microwave sources having a waveguide output facing the RF window 110. In the typical configuration, the RF energy coupled into the chamber 100 through the RF window 110 excites the processing gas into a reactive plasma for processing the wafer 108 or other reasons. However, the reactive plasma also interacts with the RF window 110 and may degrade it.

The reaction chamber 100, process gas inlets 102, exhaust port 104, chuck 106, RF energy source 114, and RF window 110 are well known in the art. Various dielectric materials, such as quartz or ceramic, for example, have been used for the RF window 110; each of the materials heretofore commonly employed present significant disadvantages. For example, while certain ceramics display acceptable thermal properties, these materials are often susceptible to damage caused by chemical reactions occurring inside the chamber 100, and consequently can introduce particulate or other contamination into the chamber 100. Although process-proven varieties of quartz may be more capable of withstanding exposure to the plasma inside chamber 100, they generally exhibit inadequate mechanical strength for large dimensioned RF windows. If the window thickness is increased in order to produce the required mechanical strength, the thermal conduction through the window is correspondingly decreased with the result that the inner surface of the window becomes hot enough to cause detrimentally affect the plasma process. As mentioned previously, yttria and YAG have superior etch resistance but are impractical for the composition of large vacuum walls, especially planar walls, due to their lower structural strengths compared with Al₂O₃-based ceramics and to their higher manufacturing costs.

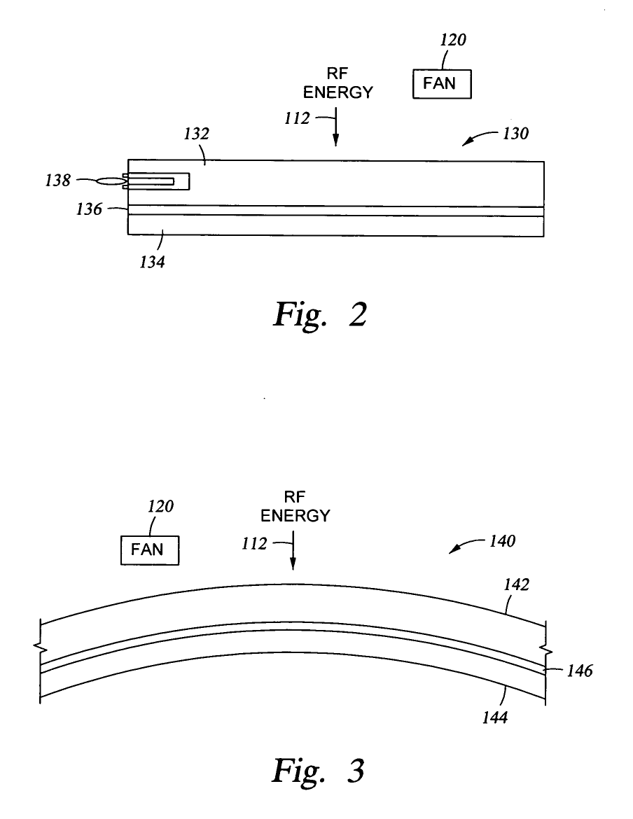

FIG. 2 is a simplified cross-sectional side view of one embodiment of a bonded multi-layer RF window 130. One reason a multi-layer RF window is beneficial is the ability to take advantage of favorable properties of materials both external and internal to the chamber, while avoiding the need to compromise between competing needs for different material properties inside and outside the chamber. In the exemplary embodiment, the RF window 130 may generally include an external layer 132 of a dielectric material facing ambient or an exterior of the chamber, an internal layer 134 of a different dielectric material facing an interior of the chamber containing the plasma for processing the wafer, and an intermediate layer 136 of bonding material disposed between the external layer 132 and the internal layer 134. In one approach, the internal and external layers 132, 134 are integral and free standing with respect to each other prior to assembly and bonding. That is, neither layer 132, 134 is deposited as a growing film upon the other.

The external layer 132, when exposed to a source of RF power, such as RF power source 114 in FIG. 1, allows transmission of RF energy therethrough. The system may include the fan 120 to circulate air across the external layer 132 to cool it. In many embodiments, the external layer 132 may account for most of the thickness of the window 130 and may provide the majority of the thermal impedance because of its thickness as well as the providing most of structural strength of the window 130. Accordingly, in addition to the required dielectric property, thermal and structural properties are important factors in selecting material for use as the external layer 132.

For example, some ceramics have superior thermal conductivity characteristics and mechanical strength as compared to other dielectric materials commonly used in RF windows. By a ceramic is meant an inorganic material other than a metal and metallic alloy, that is formed by a high temperature process. A ceramic may be a sintered material or a glass. Ceramics include alumina, quartz, yttria, YAG, and silicon nitride formed as bulk members rather than thin films. Many but not all ceramics may be characterized as metal oxides; others as metal nitrides.

The outer dielectric material may be selected such that external layer 132 efficiently transmits an acceptable amount of RF energy with relatively little absorption or attenuation, provides sufficient heat conductivity to cool the internal layer 134 (as discussed below), and provides sufficient mechanical strength to withstand forces generated by the vacuum inside the reaction chamber. Various ceramics generally possess such heat transfer properties and mechanical strength. Accordingly, ceramics may be more reliable and better suited for the external layer 132 than other dielectric materials, particularly for RF windows having large dimensions, e.g. large diameters. Aluminum nitride may be used for the external layer 132.

The inner dielectric material of the internal layer 134 needs to allow transmission of RF energy and diffusion of heat. Additionally, the internal layer 134 is exposed to plasma inside the plasma reaction chamber 100. If the internal layer 134 is kept relatively thin in comparison to the external layer 132, its dielectric constant, RF absorption, and heat diffusivity are less important than its resistance to plasma etching and its effect on the processing chemistry. Consequently, the dielectric material selected for the internal layer 134 is typically different from that selected for the external layer 132. Quartz or ceramic dielectrics of the sort well proved for semiconductor processing may be used. Different types of quartz may be used for the external and internal layers 132, 134. Importantly, the internal layer 134 should be resistant to the chemical reactions occurring in the chamber. Those of skill in the art will appreciate that the selection of material for the internal layer 134 may be a function of the particular process chemistries employed in the reaction chamber.

By way of example, varieties of quartz may withstand the environment of the plasma reaction chamber very well and introduce little or no contamination into the chamber during operation. As another example, yttrium aluminum garnet (YAG), which is a ceramic material which may be formed from mixtures of aluminum and yttrium oxides in varying proportions, may advantageously be used for facing the processing plasma. YAG and other related materials advantageously produce particulates or contaminate the chemistry in some processes. Similarly, silicon nitride may adequately withstand deterioration when subject to the plasma inside the chamber. Alumina has also been used for parts facing the plasma but it is more typically used as the external layer.

However, the material of the internal layer 134 is not limited to ceramics. Plastics and polymers of sufficient etch resistance may be adhered to the inner side of the external layer 132.

Many process-proven materials such as those mentioned above, however, may experience increases in temperature due to the transmission and partial absorption of RF energy, and consequently may become hot enough during a particular process to affect the temperature within the plasma processing region. It is also possible that the plasma heats the window to a temperature higher than that desired for the process chemistry. Many plasma processes need the temperature of the walls of the plasma chamber walls to be controlled within a desired range. In the exemplary embodiment of FIG. 2, therefore, it is desirable to conduct heat from the internal layer 134 such that the temperature of the inner surface of the window 130 does not affect the process inside the reaction chamber.

However, when the surfaces of two hard materials (such as ceramic and quartz as an exemplary combination) are clamped together less than 2% of the respective surface areas are actually in contact. On a molecular level, such a small percentage of surface area contact creates difficulties in conductive heat transfer between the surfaces. However, when the same two surfaces are bonded together using techniques known in the art, the effective contact area is significantly increased so that as much as to 95% of the respective surface areas may be in contact. As a result of bonding the two surfaces, heat conduction from one surface to the other is facilitated by virtue of the increased surface contact created by the bonding material.

Examples of Ceramics

Alumina or quartz is the preferred material for the external layer 132 and yttria or to a lesser extent YAG is the preferred material for the internal layer 134. However, the invention is not limited to these materials. Alumina and quartz of adequate strength are available at reasonable cost for substantial thickness. Yttria and YAG of high etch resistance are available but their thickness should be minimized to reduce the cost.

As illustrated in FIG. 2, the bonded multi-layer RF window 130 may include the intermediate layer 136 of bonding material disposed between the external and internal layers 132, 134. As discussed above, the bonding material provides contact over substantially the entire surface area of the external layer 132 and the internal layer 134. The broad surface area contact created by the intermediate layer 136 facilitates thermal conductivity from the internal layer 134 to the external layer 132. Heat produced by the chemical reaction inside the chamber and by the transmission of RF energy through the window 130 and resultant partial absorption of the energy may be transferred away from the internal layer 134 to the external layer 132, and the external layer 132 may be cooled by the fan 120 during a wafer fabrication process.

The bonding material used for the intermediate layer 136 should also allow transmission of RF energy. Several different types of bonding material may be used. Examples include adhesives and fusion glass layers.

Examples of adhesive composition may include polyimide or Teflon® (a hydrophobic fluorocarbon polymer), varieties of vacuum-proof epoxy, pressure sensitive adhesives (PSA). Room temperature vulcanized (RTV) silicone may also be acceptable as bonding material. Various methods of adhesive bonding are known in the art; and the most effective bonding technique is largely a function of the types of materials to be bonded as well as the bonding material selected.

As can be appreciated, a primary purpose of the bonding material is to increase the contact area between the internal and external layers. Where materials for internal and external layers have favorable contact properties, as well as the other required properties, the need for a comprehensive bonding layer may be reduced or eliminated.

Fusion glass bonding involves sandwiching a generally powdered precursor of a glass between already formed and free-standing inner and outer ceramic members, for example, of already sintered alumina and yttria. The powder may be suspended in a plastic or cellulose binder and the flowable mixture may be brushed onto one or both of the ceramic members. The two members are then assembled with a little pressure applied to the assembly. The assembly is moved to a furnace and heated to a glass melting temperature at which the powdered precursor melts to form a molten flowable glass but which is below the melting points of the two ceramic members. The temperature is then reduced in a controlled cool down but rapidly enough that the fusion glass remains in glassy form at room temperature as well as at typical operational temperatures of plasma reactors. Glasses generally wet well to ceramics and thus form a ready fusion bond between the two ceramic layers extending over the entire interface.

Examples of Fusion Glasses

For comparative purposes, the melting points for alumina, quartz, and yttria are respectively about 2040° C., 1720° C., and 1940° C. The fusion glass should have a glass forming temperature substantially below the melting points of the adjacent ceramic materials. The coefficients of thermal expansion should be maintained as equal as possible between the different materials. The fusion glass is typically formed by mixing together powders of different metal oxides in a desired compositional ratio and placing the powder mixture between two already formed inner and outer layers. If necessary, a volatile binder may hold the powders together. The assembly is pressed together while heat treated to glass fuse the assembly. The fusion bonding provides an intimate bond across the entire interface and thus promotes thermal diffusion.

Although the invention is not so limited, three fusion glass powder mixtures offer great promise, especially for glass fusion bonding of alumina and yttria: (1)Al₂O₃—SiO₂—CaO; (2) Al₂O₃—Y₂O₃—SiO₂; and (3) Al₂O₃—SiO₂—CaO. Generally, lead and magnesium should be avoided in semiconductor applications.

A thermocouple or other temperature measuring device may be employed for monitoring the temperature at one or more locations in the window 130. In the embodiment of FIG. 2, the thermocouple 138 is embedded into the external layer 132 and may be used to monitor temperature either continuously or at discrete intervals. Through use of appropriate feedback loops and electronics, a cooling system employing the fan 120 or another cooling device may provide dynamic thermal control of window 130. The use of materials with sufficiently high thermal conductivity for all layers of the window allows the temperature of the inner window surface to be controlled without detrimental oscillations in the temperature when the cooling is being controlled through the thermocouple 138.

It will be appreciated that the location of the thermocouple 138 is illustrated by way of example only and not by way of limitation. It is within the scope and contemplation of the invention to employ more than one thermocouple, for example, or to vary the annular or radial location of a temperature monitor. In one embodiment, for example, one or more temperature measuring devices may directly monitor the temperature of the internal layer 134 and the intermediate layer 136, as well as the external layer 132 as in FIG. 2.

Those skilled in the art will also appreciate that the relative thickness of each layer 132, 134, 136 in FIG. 2 is illustrated by way of example only, and not by way of limitation. As noted briefly above, the external layer 132 may provide most of the structural strength of the window 130 and may be relatively thick in comparison to the internal layer 134. In one embodiment, for example, the external layer 132 may be ceramic material having a thickness of approximately ¾″ (19 mm), while the internal layer 134 may be a plasma-resistant variety of quartz having a thickness of approximately ¼″ (6.4 mm). In such an embodiment, the intermediate layer 136 of bonding material may have a thickness of approximately 2 to 10 mm, depending upon the type of bonding material used and the method of bonding, for instance.

FIG. 3 is a simplified cross-sectional side view of another embodiment of a bonded multi-layer RF 140 window shaped as a dome, for example, a two-dimensional dome symmetric about a central axis around which is wrapped an inductive RF antenna coil. In the embodiment of FIG. 3, the RF window 140 may generally include an external layer 142 of dielectric material, an internal layer 144 of dielectric material, and an intermediate layer 146 of bonding material disposed between the external and internal layers 142, 144. The layers 142, 144, 146 may all have the same curved dome shape.

Similarly to the embodiment discussed above with reference to FIG. 2, the external layer 142 when exposed to a source of RF power allows transmission of RF energy 112 through it. The fan 120 may be included to circulate air across the exposed side of the external layer 142 to cool it and the rest of the window 140. As discussed above, the external layer 142 may be thick enough to present the majority of the heat dissipation as well as the structural integrity of window 140. Accordingly, external layer 142 may be constructed of ceramic material which transmits an acceptable percentage of RF energy for the particular application and provides appropriate levels of thermal conductivity and mechanical strength as discussed above.

The internal layer 144 (which also allows transmission of RF energy) is exposed to plasma inside a plasma reaction chamber 100. Consequently, it is desirable that the dielectric material selected for the internal layer 144 is process-proven, i.e., the internal layer 144 should be resistant to the plasma and chemical reactions occurring in the chamber. Either quartz or ceramic dielectrics (such as YAG materials or silicon nitride, for example) may be used, as discussed above.

As in the embodiment of FIG. 2, the intermediate layer 146 of bonding material (which may be polyimide, Teflon polymer, PSA, RTV silicone, or vacuum-proof epoxy, for example) is disposed between external layer 142 and internal layer 144. The bonding material provides contact over substantially the entire surface area of external layer 142 and internal layer 144 to facilitate thermal conductivity from internal layer 144 to external layer 142.

Although not illustrated in FIG. 3, one or more thermocouples or other temperature measuring devices may be employed for monitoring the temperature at one or more locations in the window 140 such that a cooling system may provide accurate thermal control of the window 140.

Whereas the window 130 in FIG. 2 may be substantially planar, the window 140 illustrated in FIG. 3 has substantial predetermined curvature. The curvature of window 140 may be used to focus RF energy in a desired location or present a more uniform plasma source region while the bonded structure of the window 140 facilitates efficient cooling of the internal layer 144.

Those of skill in the art will appreciate that the thickness and curvature of window 140 is illustrated by way of example only, and not by way of limitation. Different radii of curvature and relative thickness of each layer 142, 144, and 146 may be employed depending upon the application.

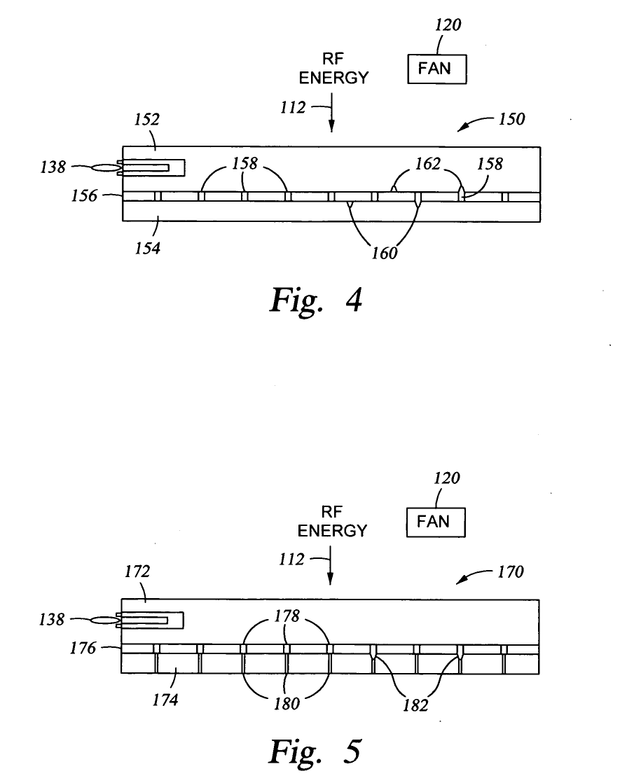

FIG. 4 is a simplified cross-sectional side view of one embodiment of a bonded multi-layer RF window 150 employing cooling conduits. An external layer 152, an internal layer 154, and an intermediate layer 156 generally correspond to layers 132, 134, and 136 discussed above. One difference between the embodiments of FIGS. 2 and 4 lies in the addition of cooling conduits 158 in the embodiment of FIG. 4. A coolant, such as water, may be circulated through the cooling conduits 158 to increase the effectiveness and the rate of heat transfer from the internal layer 154.

As illustrated in FIG. 4, the cooling conduits 158 may be created in intermediate layer 156 by providing corresponding voids 158 in the bonding material. While such voids 158 may decrease the percentage of surface area contact between the external and internal layers 152, 154, the circulation of a coolant through the cooling conduits 158 may increase the overall cooling rate of the window 150, and in particular of the internal layer 154. In one method of fabricating the cooling conduits 158, tiles of the material of the intermediate layer 156 arranged in a horizontal array are bonded to the external layer 152 with horizontally extending voids 158 or lateral gaps separating the tiles. The internal layer 152 may then be bonded to the tiles of the intermediate layer 156 bridging the voids 158. Elongated tiles may be arranged in a linear array with channels extending primarily in one direction or less elongated or square tiles may be arranged in a two-dimensional array with connected channels extending in both directions. Additionally or alternatively, cooling conduits 158 may be created by forming, prior to the assembly of the layers 152, 154, 156, channels or grooves 160 in the external layer 152, or grooves 162 in the internal layer 154, or both sets of grooves 160, 162 at their respective interfaces with the intermediate layer 156. The grooves 160, 162 may or may not be aligned with the voids 158 in the intermediate layer 156.

Where channels, grooves, or other features, such as the voids 158 in the bonding material shown in FIG. 4, for example) are used as cooling conduits, a liquid coolant supply may be circulated under pressure at a predetermined or dynamically adjusted flow rate. In this embodiment, one or more temperature monitors such as the thermocouple 138 enable a cooling system with temperature measurements from desired locations in the window 150. Control circuitry responsive to such temperature measurements may adjust the coolant flow rate in accordance with the measured temperature of the window 150. In addition to coolant flowing through the cooling conduits 158, an RF window cooling system may also employ the fan 120 for circulating air across the exposed surface of the external layer 152, as discussed above.

Those of skill in the art will appreciate that the number and arrangement of cooling conduits 158 may affect the cooling process. Specific configurations of cooling conduits 158 providing optimum cooling depend upon the materials selected for the layers 152, 154, 156 and are also highly dependent upon the application for which the chamber is being used.

FIG. 5 is a simplified cross-sectional side view of one embodiment of a bonded multi-layer RF window 170 employing gas distribution conduits and gas injection apertures forming a showerhead. An external layer 172, an internal layer 174, and an intermediate layer 176 generally correspond to layers 132, 134, 136 discussed above; however, one difference between the embodiments of FIGS. 2 and 5 resides in the addition in the embodiment of FIG. 5 of gas distribution conduits 178 formed in the intermediate layer 176 and gas injection apertures 180 formed in the internal layer 174 linking at least some of the gas distribution conduits 178 to the interior of the processing chamber 100. The gas distribution conduits 178 primarily extend horizontally to supply gas to the gas injection apertures 180, which primarily extend vertically to connect the gas distribution conduits 178 to the interior of the processing chamber 100. One or more ports formed through the external layer 172 may be used to supply the process gas to the interconnected gas distribution conduits 178. The gas distribution conduits 178 may be similar in construction to the liquid cooling conduits 158 discussed above with reference to FIG. 4. Process gases may be circulated through the gas distribution conduits 178 for injection into the plasma reaction chamber through gas injection apertures 180 in the internal layer 174 aligned to the gas distribution conduits 178.

As illustrated in FIG. 5, the gas distribution conduits 178 may be created in the intermediate layer 176 by introducing voids 178 in the bonding material of the intermediate layer 176. Additionally or alternatively, the gas distribution conduits 178 may be created by forming channels or grooves 182 in the internal layer 174 at the interface with the intermediate layer 176 in alignment to the grooves 182. The gas injection apertures 180 in combination with the gas distribution conduits 178, may be arranged in a desired pattern in the internal layer 174 to achieve a desired gas distribution within the processing area of the reaction chamber.

In operation, the window 170 may serve as a gas distribution showerhead. Process gases may be distributed under pressure, at a predetermined or dynamically adjusted flow rate, through gas distribution conduits 178 for introduction into the reaction chamber through gas injection apertures 180.

As in the embodiments previously described, a temperature monitor such as the thermocouple 138 may provide to a cooling system temperature measurements from desired locations in the window 170. Control circuitry (not shown) responsive to such temperature measurements may adjust the operation of the fan 120 for circulating air across external layer 172, as discussed above.

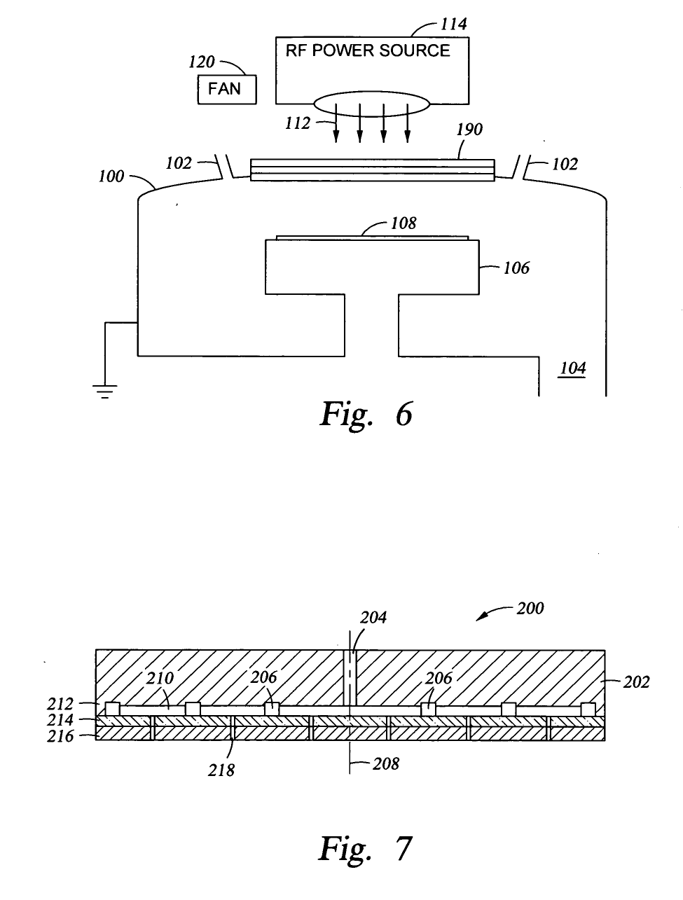

FIG. 6 is a simplified cross-sectional side view of a system employing a bonded multi-layer RF window 190 in the plasma reaction chamber 100. The reaction chamber 100 may generally include the process gas inlets 102, the process gas exhaust 104, and the pedestal 106 with electrostatic chuck for supporting and holding the wafer 108 to be processed. The RF window 190 sealed to the chamber 100 and RF energy from an RF power source 114 may be transmitted through the window 190 to the process gases inside reaction chamber 100.

The window 190 may generally correspond to the inventive bonded multi-layer RF windows described in detail above. In the embodiment of FIG. 6, for example, the window 190 may be similar to the embodiments illustrated FIGS. 2-4. It will be appreciated that if the window 190 employs gas distribution conduits and gas injection apertures such as described with reference to FIG. 5, then the process gas inlets 102 may not be necessary. Alternatively, the process gas inlets 102 may be employed to supplement the introduction of process gas into the reaction chamber through the window 190 even if the embodiment of FIG. 5 is used for the window 190.

A ceramic showerhead 200 according to one embodiment of the invention is illustrated in the cross-sectional view of FIG. 7. A ceramic back plate 202, for example, of alumina is machined to form a gas inlet port 204 on its back. Multiple, for example three, annular azimuthal distribution channels 206 are machined into the front of the back plate 202 to be circularly symmetric about a showerhead central axis 208. Multiple radial distribution channels 210 are machined across respective diameters or radii to connect the azimuth distribution channels 206 and the gas inlet port 204. The remaining portions of the front surface of the back plate 202 are left planar including a rim 212 outside of the outermost azimuthal distribution channel 206 and sealing the process gas within the window 200.

A thin bonding layer 214 of glass precursor and binder is brushed onto a surface of a ceramic front plate 216, for example, of yttria, and the back plate 202 is lowered onto the bonding layer 214 covering the front plate 216. The figure does not clearly show that the majority of the bottom of the back plate 202 contacts the bonding layer 214. The assembly is then moved to a furnace and is heated there to convert the glass precursor into a fusion glass forming the bonding layer 214. The bonding layer 214 prior to heating is thin enough, less than 1 mm, compared to the depth of the distribution channels 206, 210 that the bonding layer 214 even its molten state does not fill the distribution channels 206, 210 although there is some rounding at the bottom edges.

The fused assembly is cooled down according to the standard recipe for the glass. Thereafter, gas apertures 218 are drilled through the front plate 216 and the glassy bonding layer 214 to connect with the radial distribution channels 210 or alternatively with the azimuthal distribution channels 206.

The resultant ceramic showerhead 200 is composed completely of dielectric material so that the showerhead 200 can act also as an RF window for a RF coil placed in back of the back plate 202. However, the ceramic showerhead 700 can be used independently of the RF coil, for example, when the process gas, perhaps in an excited state, should not contact metal surfaces. Further, both ceramic layers 202, 216 may be composed of the same ceramic material especially if etch resistance of the inner layer is not a critical requirement.

The same assembly and annealing procedure may be used for a unpatterned RF window by omitting the machining steps described above in forming the showerhead.

A liquid cooled RF window can be similarly fabricated by including two ports 204 for the supply and drainage of the cooling liquid and forming the distribution channels as one or more convolute channels connecting the supply and drainage ports. No gas apertures 218 would be included for the liquid cooled RF window.

Alternatively, the ceramic back plate 202 can be constructed to contain both the distribution channels for the gas delivery and separate channels for liquid coolant, which would connect to separate supply and drainage ports for the two different types of channels. Both gas delivery and coolant channels can be constructed as channels in the bottom portion of the ceramic back plate 202 and would be isolated from each other using the combination of the bonding layer 214 and the showerhead plate 216.

Additional flexibility can be achieved in the fabrication of these channels in the base ceramic back plate 202 by the addition of a third ceramic plate between the base back plate 202 and the bonding layer 214. The third ceramic plate would be attached to the base back plate 202 with a second bonding layer, which would seal the bottom of the coolant channels. The third ceramic plate would contain a passageway for the process gas delivery and a gas distribution channel, which is connected to the gas apertures 218.

From the foregoing, it can be seen that the present invention provides effective and consistent dissipation of heat from the internal side of an RF window exposed to plasma within a reaction chamber. Furthermore, the invention is not limited to RF windows but may be advantageously applied to the vacuum walls of the a plasma processing chamber.

The embodiments disclosed herein have been described and illustrated by way of example only, and not by way of limitation; it will be apparent to those of skill in the art that numerous modifications may be made thereto without departing from the spirit and scope of the invention.

1. A multi-layer RF window for use in a plasma reaction chamber; the RF window comprising:
an external layer of a first dielectric material;
an internal layer of a second dielectric material; and
an intermediate layer of bonding material disposed between the external layer and the internal layer; wherein the internal layer is bonded to the external layer by the intermediate layer.

2. The multi-layer RF window of claim 1 wherein the external layer has a higher mechanical strength than the internal layer.

3. The multi-layer RF window of claim 1, wherein the first and second dielectric materials comprise respective ceramics.

4. The multi-layer RF window of claim 3, wherein the second dielectric material comprises quartz.

5. The multi-layer RF window of claim 1, wherein the first dielectric material is a first ceramic and the second dielectric material is a second ceramic different from the first ceramic.

6. The multi-layer RF window of claim 1, wherein the first dielectric material is alumina and the second dielectric material is one of yttria and yttrium aluminum garnet.

7. The multi-layer RF window of claim 1, further comprising cooling conduits formed at an interface between neighboring ones of the layers.

8. The multi-layer RF window of claim 6, further comprising a cooling system controlling flow of a coolant through the cooling conduits responsive to temperature measurements of the RF window.

9. The multi-layer RF window of claim 7, wherein the cooling conduits are located at an interface between the external layer and the intermediate layer.

10. The multi-layer RF window of claim 7, wherein the cooling conduits are located at an interface between the internal layer and the intermediate layer.

11. The multi-layer RF window of claim 1, further comprising gas distribution conduits in the intermediate layer and gas injection apertures in the internal layer; the gas distribution conduits and the gas injection apertures cooperating to deliver one or more process gases into the plasma reaction chamber.

12. The multi-layer RF window of claim 1 wherein the bonding material is selected from the group consisting of polyimide, Teflon polymer, epoxy, pressure sensitive adhesive, and RTV silicone.

13. The multi-layer RF window of claim 1, wherein the bonding material is an oxide glass.

14. The method of fabricating an RF window for coupling RF energy into a plasma reaction chamber; the method comprising:
providing a free-standing first layer of a first dielectric material;
providing a free-standing second layer of a second dielectric different than the first dielectric material; and
bonding the first layer to the second layer with a bonding material.

15. The method of claim 14, wherein the bonding material is an adhesive.

16. The method of claim 14, wherein the bonding material is ceramic material.

17. The method of claim 14, wherein the first and second dielectric materials are oxide ceramics and the bonding material is an oxide glass having a glass forming temperature less than melting temperatures of the first and second dielectric material and the bonding step includes assembling the first and second layer in an assembly with the bonding material disposed therebetween and heating the assembly to a temperature greater than glass forming temperature and less than both of the melting temperatures.

18. The method of claim 14, wherein the first dielectric material comprises alumina, the second dielectric material comprises a selected one of yttria and yttrium aluminum garnet, and the bonding material comprises an oxide glass having a glass forming temperature lower than the melting points of alumina and the selected one of yttria and yttrium aluminum garnet.

19. The method of claim 14, wherein the oxide glass is formed from a powder selected from the set of component powders selected from the group consisting of: (1) Al₂O₃—SiO₂—CaO; (2) Al₂O₃—Y₂O₃—SiO₂;(3) Al₂O₃—SiO₂—, and mixtures thereof.

20. A plasma processing system, comprising:
a plasma reaction chamber; and
a multi-layer dielectric wall of the plasma reaction chamber comprising
an external layer of a first dielectric material,
an internal layer of a second dielectric material facing an interior of the plasma reaction chamber, and
an intermediate layer of bonding material bonding the external layer to the internal layer.

21. The system of claim 20, wherein the external layer has a higher mechanical strength than the internal layer.

22. The system of claim 20, wherein the internal layer is more resistant to plasma processing conditions within the plasma reaction chamber than is the external layer.

23. The system of claim 20, wherein the first and second dielectric materials are respective ceramics.

24. The system of claim 20, wherein the dielectric wall forms an RF window for an RF source disposed externally to the plasma reaction adjacent the dielectric wall.

25. The system of claim 24, wherein the RF window includes cooling conduits.

26. The system of claim 20, wherein the dielectric wall includes:
gas distribution channels formed at an interface between the external and intermediate layers; and
gas injection apertures form in the internal layer and wherein the system delivers one or more process gases into the plasma reaction chamber through the gas distribution conduits and the gas injection apertures.

27. The system of claim 14, wherein the bonding material is selected from the group consisting of polyimide, Teflon (tm), epoxy, pressure sensitive adhesive, and RTV silicone.

28. A multi-layer RF window for use in a plasma reaction chamber; the RF window comprising:
an external layer of a first dielectric material; and
an internal layer of a second dielectric material in contact with the external layer over substantially the entire surface area of external layer.

29. The multi-layer RF window of claim 28, further comprising an intermediate layer of bonding material disposed between the external layer and the internal layer, wherein the internal layer is bonded to the external layer by the intermediate layer.

30. The multi-layer RF window of claim 28, wherein the first dielectric material is ceramic and the second dielectric material is quartz.

31. The multi-layer RF window of claim 28, wherein the first dielectric material is ceramic and the second dielectric material is ceramic.

32. The multi-layer RF window of claim 28, further comprising cooling conduits formed therein.
